(19) United States
(12) Patent Application Publication
(10) Pub. No.: US 2024/0213738 A1
(43) Pub. Date: Jun. 27, 2024

(54) METHOD FOR MANUFACTURING BASE PORTION FOR LIGHT-EMITTING DEVICE, METHOD FOR MANUFACTURING LIGHT-EMITTING DEVICE, AND LIGHT-EMITTING DEVICE

(71) Applicant: NICHIA CORPORATION, Anan-shi (JP)

(72) Inventor: Masatoshi NAKAGAKI, Komatsushima-shi (JP)

(21) Appl. No.: 18/396,443

(22) Filed: Dec. 26, 2023

(30) Foreign Application Priority Data
Dec. 27, 2022 (JP) 2022-209675

(51) Int. Cl. H01S 5/02255

(52) U.S. Cl. CPC H01S 5/02255

(57) ABSTRACT

A method for manufacturing a base portion configured to be used in a light-emitting device includes: providing a base body, the base body including a substrate formed of a metal material, the substrate having an upper surface, and a frame body formed of ceramics, the frame body being located around the upper surface of the substrate; and forming a recessed portion in the upper surface of the substrate, the recessed portion having a bottom surface including a planar region.

### CROSS-REFERENCE TO RELATED APPLICATION

This application claims priority to Japanese Patent Application No. 2022-209675, filed on Dec. 27, 2022, the disclosure of which is hereby incorporated herein by reference in its entirety.

### TECHNICAL FIELD

The present disclosure relates to a method for manufacturing a base portion to be used for a light-emitting device, a method for manufacturing a light-emitting device, and a light-emitting device.

### BACKGROUND

Light-emitting devices including a semiconductor laser element can be used for devices such as a projector and a lighting light source. Such light-emitting devices may cause a traveling direction of a laser beam emitted to the outside of the light-emitting devices to deviate from a designed traveling direction due to a manufacturing error or deformation of a structure in a manufacturing process. See, for example, Japanese Patent Publication No. 2002-231864.

### SUMMARY

Reducing a deviation between a traveling direction of a laser beam emitted to the outside of a light-emitting device and a designed traveling direction has been expected.

In an embodiment, a method for manufacturing a base portion for a light-emitting device according to the present disclosure includes: providing a base body, the base body including a substrate formed of a metal material, the substrate having an upper surface, and a frame body formed of ceramics, the frame body being located around the upper surface of the substrate; and forming a recessed portion in the upper surface of the substrate, the recessed portion having a bottom surface including a planar region.

In an embodiment, a method for manufacturing a light-emitting device according to the present disclosure includes manufacturing a base portion by the method for manufacturing a base portion described above; and disposing a semiconductor laser element on the bottom surface of the recessed portion.

In an embodiment, a light-emitting device according to the present disclosure includes a substrate, a semiconductor laser element, a mirror member, and a frame body. The substrate is formed of a metal material and has an upper surface, the upper surface defining a recessed portion having a bottom surface. The bottom surface includes a planar region. The semiconductor laser element is disposed on the bottom surface of the recessed portion and configured to emit a laser beam. The mirror member is disposed on the bottom surface of the recessed portion and configured to reflect the laser beam to change a traveling direction of the laser beam in a direction away from the upper surface of the substrate. The frame body is formed of ceramics and surrounds the semiconductor laser element and the mirror member.

An embodiment of the present disclosure can reduce a deviation between a traveling direction of a laser beam emitted to the outside of a light-emitting device and a designed traveling direction.

### BRIEF DESCRIPTION OF DRAWINGS

FIG. 1A is a perspective view schematically illustrating a configuration of a light-emitting device according to an exemplary embodiment of the present disclosure.

FIG. 1B is an exploded perspective view of the light-emitting device illustrated in FIG. 1A.

FIG. 1C is an exploded perspective view of the lowermost structure of the light-emitting device illustrated in FIG. 1B.

FIG. 1D is a perspective view of a frame body included in the light-emitting device illustrated in FIG. 1A as seen from below.

FIG. 1E is a top view of a configuration of the light-emitting device illustrated in FIG. 1A with a cover and an optical member omitted.

FIG. 1F is a cross-sectional view parallel to a YZ plane of the light-emitting device illustrated in FIG. 1A.

FIG. 1G is a cross-sectional view in which part of an upper surface of a substrate is modified from the configuration illustrated in FIG. 1F.

FIG. 2A is a cross-sectional view parallel to the YZ plane, schematically illustrating a configuration of a modified example of the light-emitting device according to the present embodiment. FIG. 2B is a top view of a configuration of a base portion to be used for the light-emitting device illustrated in FIG. 2A.

FIG. 3A is a cross-sectional view parallel to the YZ plane for illustrating an example of a process of a method for manufacturing a base portion to be used for the light-emitting device according to the present embodiment.

FIG. 3B is a cross-sectional view parallel to the YZ plane for illustrating an example of a process of a method for manufacturing a base portion to be used for the light-emitting device according to the present embodiment.

FIG. 3C is a cross-sectional view parallel to the YZ plane for illustrating an example of a process of a method for manufacturing a base portion to be used for the light-emitting device according to the present embodiment.

FIG. 4A is a cross-sectional view parallel to the YZ plane for illustrating an example of a process of a method for manufacturing a base portion to be used in a modified example of the light-emitting device according to the present embodiment.

FIG. 4B is a cross-sectional view parallel to the YZ plane for illustrating an example of a process of a method for manufacturing a base portion to be used in a modified example of the light-emitting device according to the present embodiment.

### DETAILED DESCRIPTIONS

Hereinafter, a light-emitting device, a method for manufacturing a base portion to be used for the light-emitting device, and a method for manufacturing the light-emitting device according to embodiments of the present disclosure will be described with reference to the drawings. Parts having the same reference numerals appearing in the plurality of drawings indicate identical or equivalent parts.

The embodiment described below is exemplified to embody a technical idea of the present invention, and the present disclosure is not limited to the following. The descriptions of dimensions, materials, shapes, relative arrangements, and the like of components are not intended to limit the scope of the present invention thereto but intended to be illustrative. The size and positional relationship of members illustrated in the drawings may be exaggerated to facilitate understanding.

In the present description or the scope of claims, polygons such as triangles or quadrangles, including shapes in which the corners of the polygons are rounded, chamfered, beveled, or coved, are referred to as polygons. A shape obtained by processing not only the corners (ends of sides), but also an intermediate portion of a side is also referred to as a polygon. In other words, a shape partially processed while leaving a polygon shape as a base is included in the interpretation of “polygon” described in the present description and the scope of claims.

### EMBODIMENTS

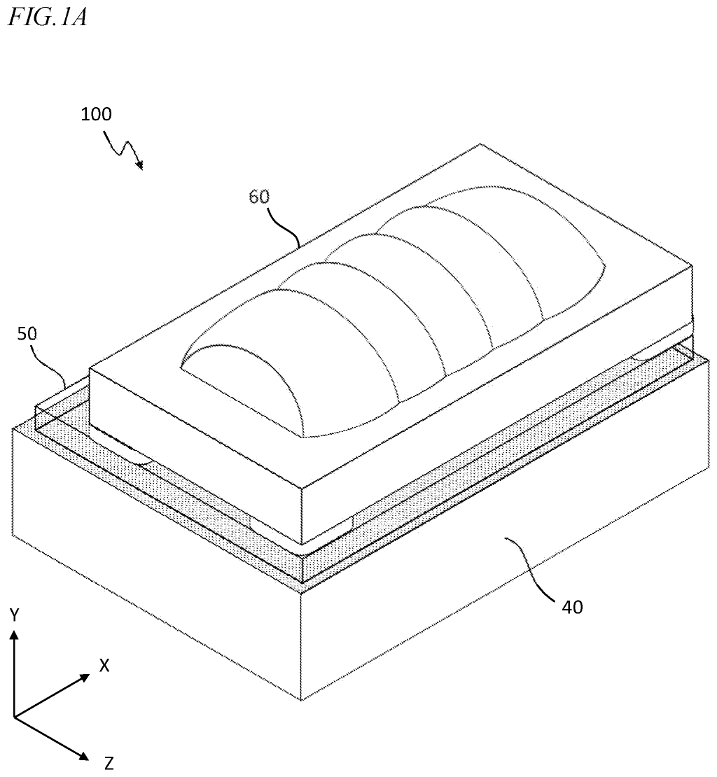

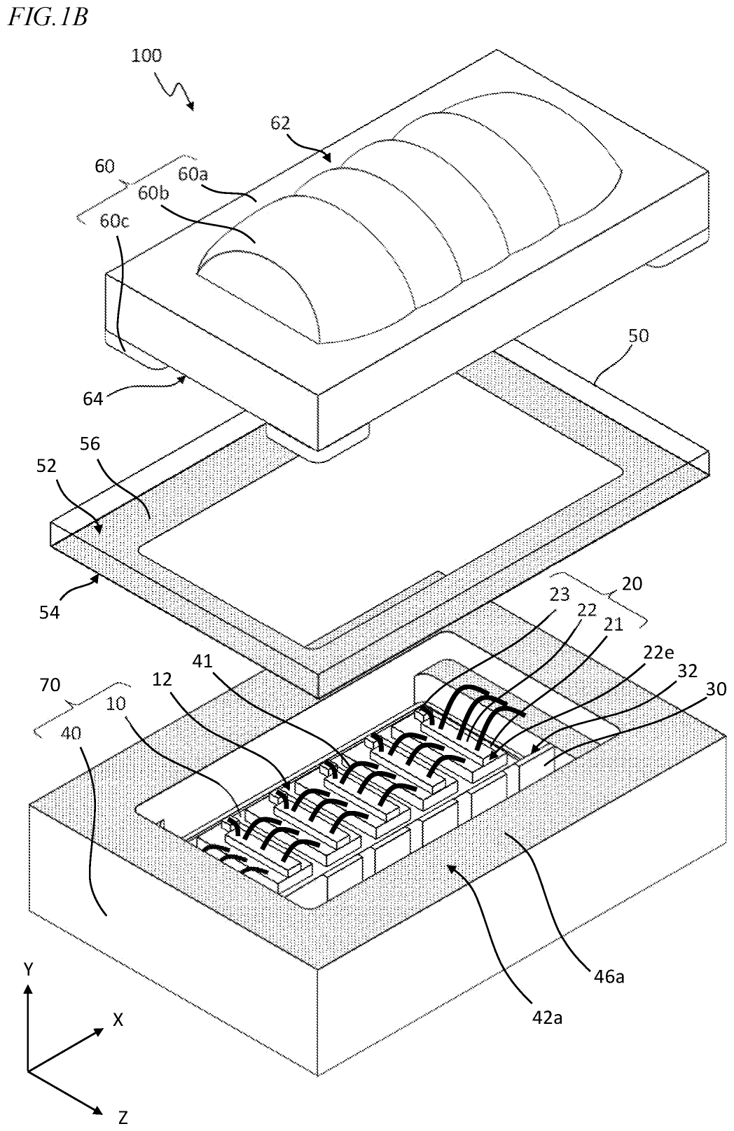

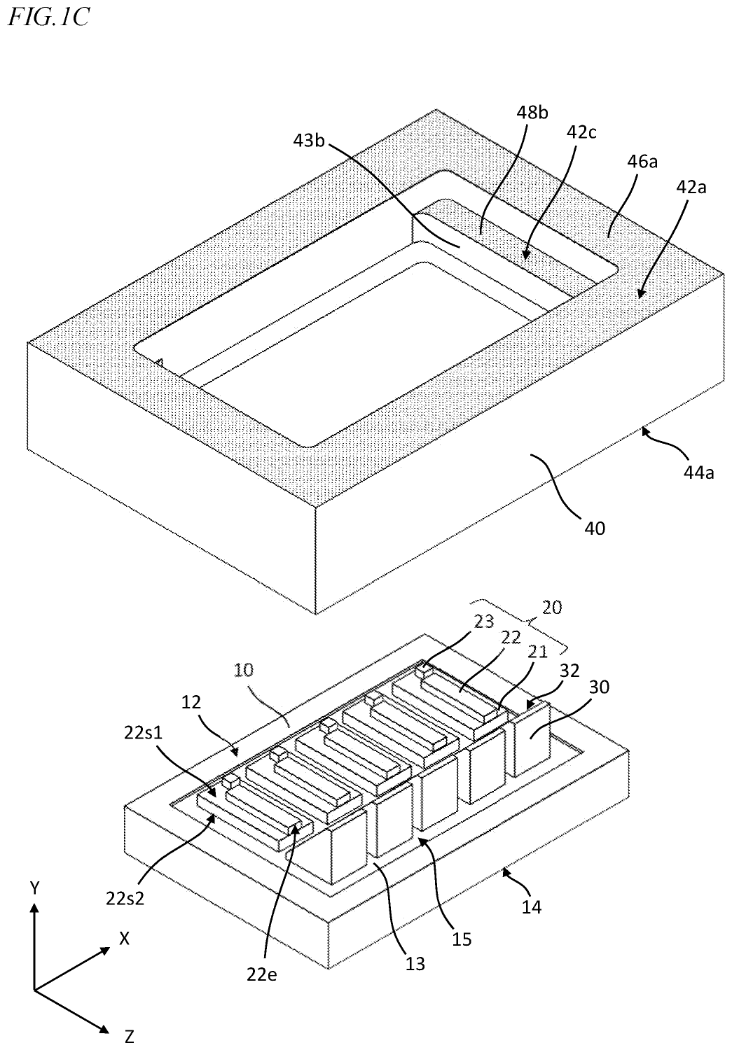

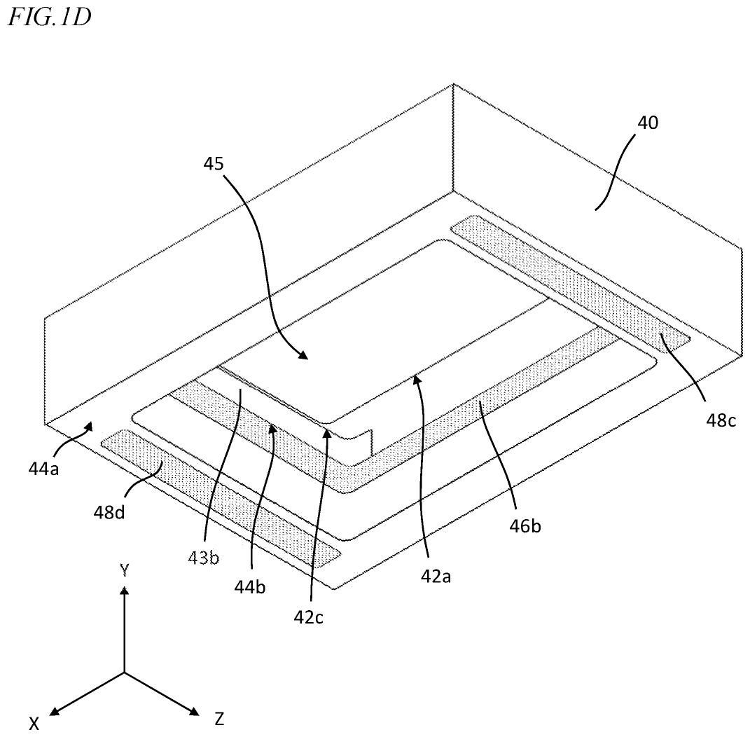

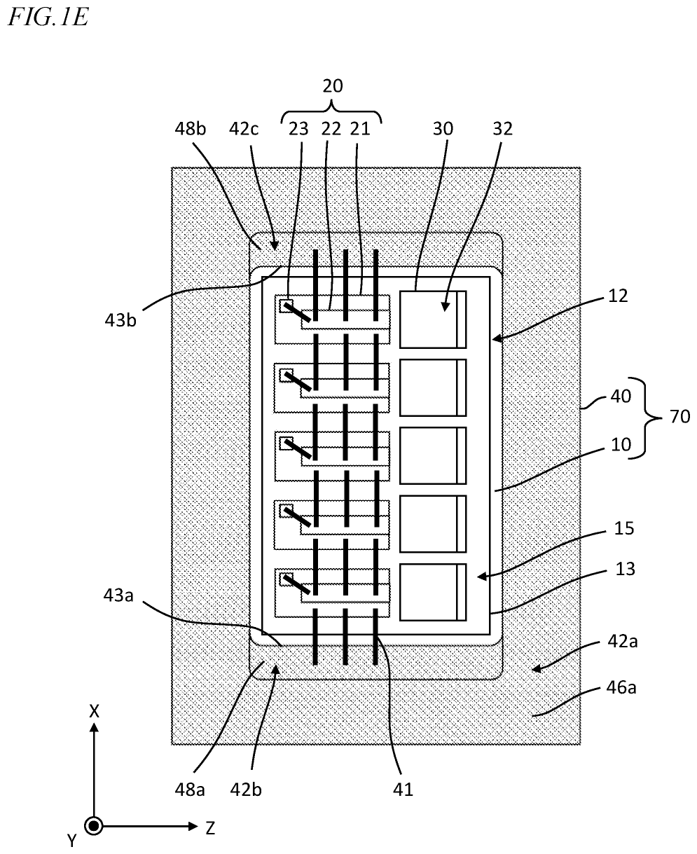

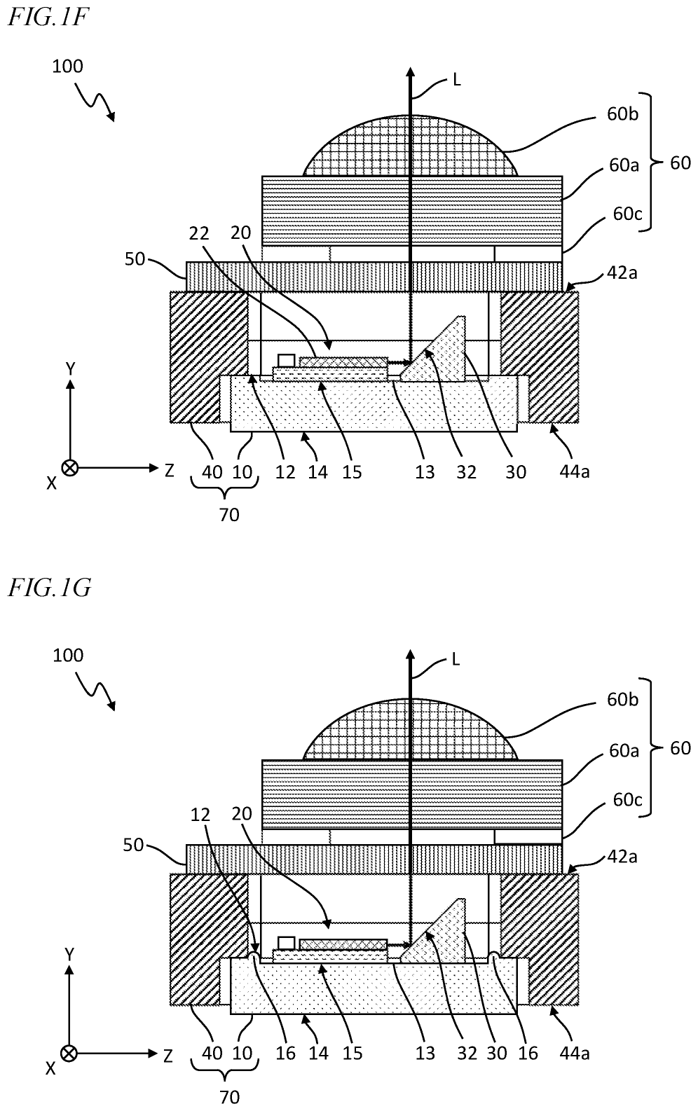

Hereinafter, a configuration example of a light-emitting device according to an embodiment of the present disclosure will be described with reference to FIGS. 1A and 1B. FIG. 1A is a perspective view schematically illustrating a configuration of a light-emitting device according to the exemplary embodiment of the present disclosure. FIG. 1B is an exploded perspective view of the light-emitting device illustrated in FIG. 1A. A light-emitting device 100 illustrated in FIGS. 1A and 1B outputs a laser beam emitted from an internal semiconductor laser element to the outside of the light-emitting device 100.

As illustrated in FIG. 1B, the light-emitting device 100 includes a substrate 10, a plurality of laser light sources 20, a plurality of mirror members 30, a frame body 40, a plurality of wires 41, a cover 50, and an optical member 60. The substrate 10 has an upper surface 12. Each of the laser light sources 20 is a chip-on-submount type semiconductor laser light source including a semiconductor laser element 22. Each of the mirror members 30 has a reflective surface 32. In the present description, a configuration in which the substrate 10 is bonded to the frame body 40 is also referred to as a “base portion 70”. The base portion 70 accommodates the plurality of laser light sources 20 and the plurality of mirror members 30.

The wavelengths of the plurality of laser beams emitted from each of the laser light sources 20 may be all the same or may be all different. Alternatively, among the wavelengths of the plurality of laser beams, the wavelengths of some laser beams may be the same, and the wavelengths of the remaining laser beams may be different from the wavelengths of the same laser beams.

In the example illustrated in FIG. 1B, the number of the laser light sources 20 is five, but is not limited to this number. The number of the laser light sources 20 may be one or more. That is, the number of the laser light sources 20 is at least one. The same applies to the number of the mirror members 30. The number of the mirror members 30 may be the same as the number of laser light sources 20. Further, only one mirror member 30 may be provided for the plurality of laser light sources 20, and the one mirror member 30 may be disposed so that the one mirror member 30 reflects the plurality of laser beams.

These drawings schematically illustrate an X-axis, a Y-axis, and a Z-axis that are orthogonal to one another for reference. The direction of an arrow on the X-axis is referred to as a +X direction, and an opposite direction thereof is referred to as a −X direction. When the ±X directions are not distinguished, the ±X directions are simply referred to as X directions. The same applies to a Y direction and a Z direction. For ease of description, the present description refers to the +Y direction as “upward” and the −Y direction as “downward.” This does not limit the orientation of the light-emitting device 100 during use, and the orientation of the light-emitting device 100 is arbitrary.

FIG. 1C is an exploded perspective view of the lowermost structure of the light-emitting device 100 illustrated in FIG. 1B. FIG. 1C omits the plurality of wires 41 illustrated in FIG. 1B. FIG. 1D is a perspective view of the frame body 40 included in the light-emitting device 100 illustrated in FIG. 1A, as seen from below. FIG. 1E is a top view of a configuration of the light-emitting device 100 illustrated in FIG. 1A with the cover 50 and the optical member 60 omitted. FIG. 1F is a cross-sectional view parallel to a YZ plane of the light-emitting device 100 illustrated in FIG. 1A. A thick arrow illustrated in FIG. 1F of the drawing indicates a traveling direction of a laser beam L emitted from the laser light source 20. FIG. 1G is a view in which part of the upper surface 12 of the substrate 10 is modified from the configuration illustrated in FIG. 1F.

In the light-emitting device 100 according to the present embodiment, a recessed portion 13 having a bottom surface 15 is provided on the upper surface 12 of the substrate 10 as illustrated in FIG. 1C. The plurality of laser light sources 20 are disposed in a line along the X direction on the bottom surface 15 of the recessed portion 13. The same as or similar to the laser light sources 20, the plurality of mirror members 30 are disposed in a line along the X direction on the bottom surface 15 of the recessed portion 13. Each of the mirror members 30 is disposed to be located in front of the corresponding laser light source 20, assuming that the traveling direction of the laser beams emitted from the laser light sources 20 is the front direction of the laser light sources 20. As illustrated in FIG. 1F, the laser beam L emitted from each of the laser light sources 20 is reflected by the reflective surface 32 of the corresponding mirror member 30, travels in a direction away from the upper surface 12, and passes through the cover 50 and the optical member 60 in this order. In this manner, the light-emitting device 100 emits the laser beam L from the optical member 60.

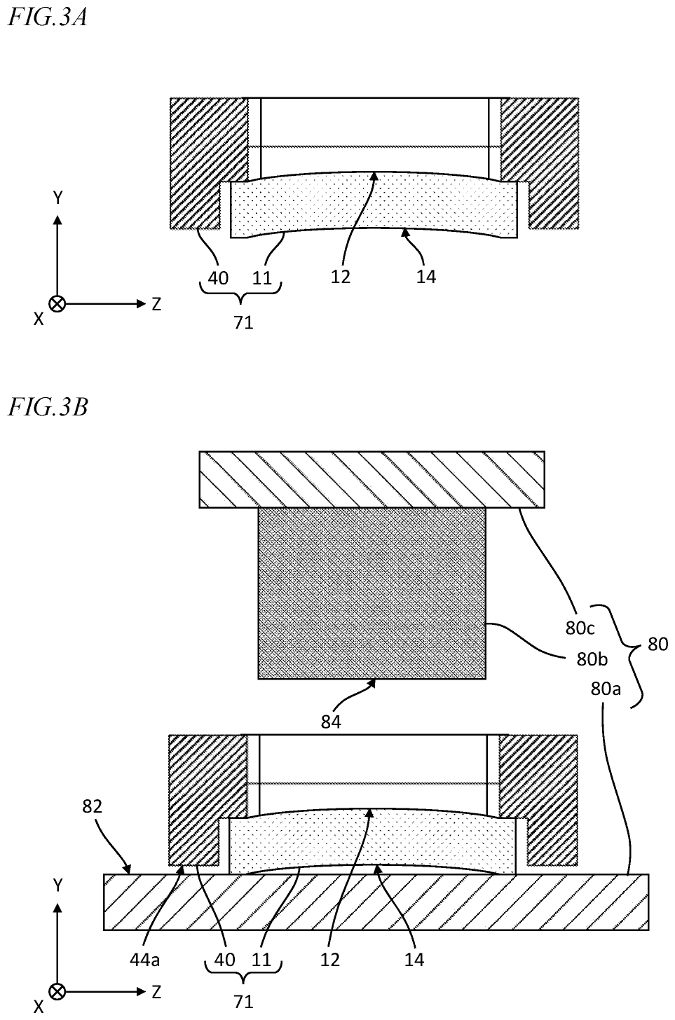

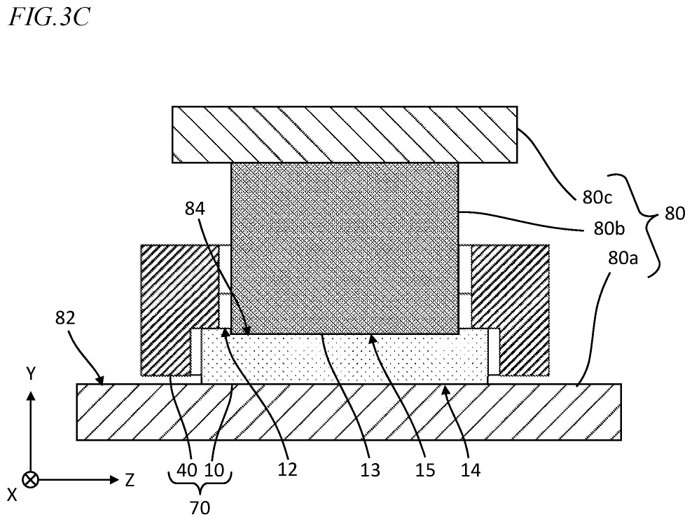

Unlike the light-emitting device 100 according to the present embodiment, a configuration in which the recessed portion 13 is not provided in the upper surface 12 of the substrate 10, like the example illustrated in FIG. 3A, may cause the following problem. When a substrate having no recessed portion on the upper surface is bonded to the frame body 40 via an inorganic bonding member such as a brazing material, heat is applied to the inorganic bonding member. When a thermal expansion coefficient of the substrate is higher than a thermal expansion coefficient of the frame body 40, the substrate is deformed more than the frame body 40 is deformed due to heat applied to the inorganic bonding member. As a result, the substrate may warp upward in a convex shape. For example, when the substrate 10 is formed of a metal material and the frame body 40 is formed of ceramics having a lower thermal expansion coefficient than the substrate 10, warpage of the substrate may be generated. In the present description, a configuration in which the substrate having no recessed portion on the upper surface is bonded to the frame body 40 is also referred to as a “base body”.

As the example illustrated in FIG. 1F, when replacing the base portion 70 with a base body and disposing the plurality of laser light sources 20 and the plurality of mirror members 30 on the upper surface of the substrate warped upward, a relative positional relationship between each of the laser light sources 20 and the corresponding mirror member 30 is shifted. This causes the traveling direction of the laser beam L emitted from each laser light source 20 to deviate from the +Z direction and the traveling direction of the laser beams L emitted from the laser light sources 20 and reflected by the reflective surface 32 of each corresponding mirror member 30 to deviate from the +Y direction. As a result, the traveling direction of the laser beam L emitted to the outside of the light-emitting device 100 deviates from the +Y direction which is the designed traveling direction.

On the other hand, in the light-emitting device 100 according to the present embodiment, when the substrate 10 is formed of a metal material, the substrate 10 has plasticity, and thus the recessed portion 13 can be provided on the upper surface 12 of the substrate 10 by a press apparatus. The press apparatus may include, for example, a stage having a planar support surface and a pressing portion having a planar lower end.

The lower end of the pressing portion can be adjusted to be parallel to the support surface of the stage. The base body is disposed on the stage of the press apparatus such that the lower surface of the substrate faces downward, and the upper surface of the substrate is pressed by the pressing portion, whereby the recessed portion is formed in the upper surface of the substrate. In this manner, the substrate 10 provided with the recessed portion 13 on the upper surface 12 is obtained. The pressing allows the warpage of the bottom surface 15 of the recessed portion 13 to be reduced and more specifically makes the bottom surface 15 planar as compared with the upper surface of the substrate before the recessed portion is provided.

Disposing the plurality of laser light sources 20 and the plurality of mirror members 30 on such a bottom surface 15 can reduce the deviation of the relative positional relationship between each laser light source 20 and the corresponding mirror member 30. Therefore, the deviation between the traveling direction of the laser beam L emitted from each laser light source 20 and the +Z direction can be reduced, and the deviation between the traveling direction of the laser beam L emitted from each laser light source 20 and reflected by the reflective surface 32 of the corresponding mirror member 30 and the +Y direction can be reduced. As a result, the deviation between the traveling direction of the laser beam L emitted to the outside of the light-emitting device 100 and the +Y direction which is the designed traveling direction can be reduced. The designed traveling direction is not limited to the +Y direction, and is any direction.

Components of the light-emitting device 100 will be described below.

### Substrate 10

The substrate 10 has the upper surface 12 as illustrated in FIG. 1C. The recessed portion 13 having the bottom surface 15 is provided on the upper surface 12. The substrate 10 further has a lower surface 14 opposite the upper surface 12. The bottom surface 15 has a planar shape parallel to the XZ plane. Similar to the bottom surface 15, the lower surface 14 has a planar shape parallel to the XZ plane. The bottom surface 15 and the lower surface 14 are parallel to each other. In this manner, the bottom surface 15 has a planar region. The same as the bottom surface 15, the lower surface 14 has a planer region. The normal direction of the bottom surface 15 is the +Y direction. In the present description, the normal direction of a surface means a direction perpendicular to the surface and away from an object having the surface. The effects obtained by the bottom surface 15 being planar, the lower surface 14 being planar, and the bottom surface 15 and the lower surface 14 being parallel to each other will be described below.

When the distance in the Y direction from the highest point in the upper surface 12 to the bottom surface 15 is a depth of the recessed portion 13 by using the lower surface 14 of the substrate 10 as a height reference, the depth of the recessed portion 13 can be, for example, 5 μm or more and 50 μm or less. The flatness of the bottom surface 15 is, for example, 10 μm or less, and the flatness of the lower surface 14 is, for example, 50 μm or less.

According to JIS B 0621 “Definitions and Designations of Geometrical Deviations,” the flatness is defined as “the magnitude of deviation from a geometrically correct plane (geometric plane) of a planar body.” Specifically, the flatness corresponds to a distance between two completely flat virtual planes when the target surface is interposed between the two virtual planes from above and below.

In the example illustrated in FIG. 1C, the substrate 10 has a substantially flat-plate shape, and the shape of the substrate 10 in a top view as seen along the +Y direction is a rectangle. The shape of the substrate 10 in a top view is not limited to a rectangle. The shape of the substrate 10 in a top view may be, for example, a polygon, a circle, or an ellipse. The thermal conductivity of the substrate 10 can be, for example, 50 W/m·K or more and 500 W/m·K or less. The substrate 10 having such thermal conductivity allows heat generated from the laser light source 20 during driving to be effectively transferred to the support surface via the substrate 10.

The thermal expansion coefficient of the substrate 10 can be, for example, 10×10⁻⁶ [1/K] or more and 20×10⁻⁶ [1/K] or less. When the thermal expansion coefficient of the substrate 10 is higher than the thermal expansion coefficient of the frame body 40 and a substrate having no recessed portion on the upper surface is bonded to the frame body 40 via an inorganic bonding member such as a brazing material, the substrate may warp upward due to heat applied to the inorganic bonding member as described above. When the substrate has plasticity, a recessed portion is provided on the upper surface of the substrate by a processing method such as pressing, whereby the substrate 10 illustrated in FIG. 1C is obtained. The warpage of the bottom surface 15 of the recessed portion 13 is reduced, and more specifically, the bottom surface 15 of the recessed portion 13 becomes planar, as compared with the upper surface before the recessed portion is provided. When the recessed portion 13 is provided by pressing, a raised portion 16 may be generated around the recessed portion 13 as illustrated in FIG. 1G. The raised portion 16 that does not interfere with the point where the substrate 10 and the frame body 40 are bonded is not a problem because the raised portion 16 does not adversely affect the bonding strength between the substrate 10 and the frame body 40.

The substrate 10 may be formed of, for example, at least one metal material selected from the group consisting of Cu, Al, and Ag. The metal material satisfies the above-described thermal conductivity and thermal expansion coefficient, and has plasticity. The size of the substrate 10 in the X direction may be, for example, 1 mm or more and 20 mm or less, the size thereof in the Y direction may be, for example, 0.1 mm or more and 5 mm or less, and the size thereof in the Z direction may be, for example, 1 mm or more and 20 mm or less.

### Laser Light Source 20

As illustrated in FIG. 1C, the plurality of laser light sources 20 are disposed in a line along the X direction on the bottom surface 15 of the recessed portion 13 of the substrate 10. In the example illustrated in FIG. 1C, the plurality of laser light sources 20 are disposed at equal intervals, but the present invention is not limited to this example. The interval between two laser light sources 20 adjacent to each other among the plurality of laser light sources 20 may be uniform or non-uniform. The interval is a distance between the centers of the two laser light sources 20.

The laser light source 20 includes a submount 21, an edge-emitting semiconductor laser element 22 supported by the submount 21, and a protecting element 23 supported by the submount 21. The semiconductor laser element 22 is disposed on the bottom surface 15 of the recessed portion 13 via the submount 21. The semiconductor laser element 22 is disposed to emit the laser beam L toward the reflective surface 32 of the mirror member 30. When the plurality of laser light sources 20 are disposed, the bottom surface 15 of the recessed portion 13 is a flat plane, allowing the deviation of the relative positional relationship between the laser light sources 20 from the design value to be suppressed.

When an excessive current flows through the semiconductor laser element 22, the semiconductor laser element 22 may be broken. As illustrated in FIG. 1B, the protecting element 23 is electrically connected to the semiconductor laser element 22 via the wire 41 and prevents an excessive current from flowing through the semiconductor laser element 22. The protecting element 23 is not necessarily provided. Only one protecting element 23 may be provided for the light-emitting device 100. In this case, the protecting element 23 may be provided on the submount 21, or may be provided on a second upper surface 42b or a third upper surface 42c of the frame body 40. The components of the laser light source 20 may be treated as components of the light-emitting device 100.

The semiconductor laser element 22 emits the laser beam L from an emission surface 22e. When the emission surface 22e is a plane parallel to the XY plane whose longitudinal direction is the X direction, the laser beam L emitted from the semiconductor laser element 22 in the +Z direction spreads relatively fast in the YZ plane and spreads relatively slowly in the XZ plane. The fast axis direction of the laser beam L is parallel to the Y direction, and the slow axis direction is parallel to the X direction.

Because the semiconductor laser element 22 is raised by the submount 21, substantially all of the laser beams L spreading while traveling can be made incident on the reflective surface 32 of the mirror member 30. The laser beam L spreading while traveling is reflected by the reflective surface 32, passes through the cover 50, and is then collimated, diffused, or focused by the optical member 60 to be described below.

The laser light source 20 disposed on the planner-shaped bottom surface 15 emits the laser beam L in the +Z direction parallel to the bottom surface 15 of the recessed portion 13 as illustrated in FIG. 1F. The traveling direction of the laser beam L emitted from the laser light source 20 does not need to be strictly parallel to the +Z direction, and the absolute value of the angle between the traveling direction of the laser beam L emitted from the laser light source 20 and the +Z direction of 0.5° or less is allowable. A specific configuration of the laser light source 20 will be described below.

As illustrated in FIG. 1F, the semiconductor laser element 22 included in the laser light source 20 is sealed by the substrate 10, the frame body 40, and the cover 50. This seal is preferably a hermetic seal. The effect of the hermetic seal increases the shorter the wavelength of the laser beam L emitted from the semiconductor laser element 22. This is because, in a configuration in which the emission surface 22e of the semiconductor laser element 22 is not hermetically sealed and is in contact with the outside air, the shorter the wavelength of the laser beam L is, the higher the possibility that deterioration of the emission surface 22e progresses during operation due to dust collection is. That is, hermetically sealing the semiconductor laser element 22 can protect the emission surface 22e of the semiconductor laser element 22 from dust collection.

Instead of the laser light source 20 including the edge-emitting semiconductor laser element 22, a surface-emitting semiconductor laser element such as a vertical-cavity surface-emitting laser (VCSEL) element may be used. The surface-emitting semiconductor laser element is disposed such that a laser beam emitted from the semiconductor laser element travels in the +Z direction. Alternatively, a surface-emitting semiconductor laser element may be disposed such that a laser beam emitted from the semiconductor laser element travels in the +Y direction. In this case, it is not necessary to provide the mirror member 30.

### Mirror Member 30

As illustrated in FIG. 1C, the plurality of mirror members 30 are disposed in a line along the X direction on the bottom surface 15 of the recessed portion 13 of the substrate 10. Each of the mirror members 30 is disposed to be located in the traveling direction of the laser beam emitted from the corresponding laser light source 20.

The mirror member 30 has a uniform cross-sectional shape in the X direction. The cross-sectional shape is substantially triangular. The mirror member 30 has a lower surface, a rear surface, and an inclined surface connecting the lower surface and the rear surface. The lower surface is parallel to the XZ plane and the rear surface is parallel to the XY plane. The normal direction of the inclined surface is a direction that is parallel to the YZ plane, forms an acute angle with the +Y direction, and forms an acute angle with the −Z direction. An angle formed between the lower surface and the inclined surface of the mirror member 30 is 45°, but is not limited to this angle, and may be 30° or more and 60° or less, for example.

The mirror member 30 has the reflective surface 32 having a planar shape. The reflective surface 32 is inclined with respect to the upper surface 12 of the substrate 10 and faces obliquely upward. In the present description, “obliquely upward” means a direction forming an angle of 30° or more and 60° or less with the +Y direction. The normal direction of the reflective surface 32 may or may not be parallel to the YZ plane as long as the reflective surface 32 can receive the laser beam L emitted from the laser light source 20 and the normal direction of the reflective surface 32 is a direction forming an angle of 30° or more and 60° or less with the +Y direction.

The reflective surface 32 of the mirror member 30 disposed on the planner-shaped bottom surface 15 reflects the laser beam L emitted from the laser light source 20 to change the traveling direction of the laser beam L to a direction away from the upper surface 12 of the substrate 10, as illustrated in FIG. 1F. In the example illustrated in FIG. 1F, the direction away from the upper surface 12 of the substrate 10 is the +Y direction perpendicular to the bottom surface 15 of the recessed portion 13. The traveling direction of the laser beam L reflected by the reflective surface 32 does not need to be strictly parallel to the +Y direction, and the absolute value of the angle formed by the traveling direction of the laser beam L reflected by the reflective surface 32 and the +Y direction of 0.5° or less is allowable. In this manner, the deviation between the traveling direction of the laser beam L emitted to the outside of the light-emitting device 100 and the +Y direction which is the designed traveling direction can be reduced.

The mirror member 30 includes, for example, a stand having an inclined surface and a reflective surface provided on the inclined surface. The stand may be formed of, for example, at least one selected from the group consisting of glass, quartz, synthetic quartz, sapphire, ceramics, silicon, metal, and a dielectric material. The reflective surface may be formed from a reflective material, such as a dielectric multilayer film and a metal material, for example. The above-mentioned reflective surface corresponds to the reflective surface 32.

Alternatively, the mirror member 30 includes, for example, a stand having an inclined surface, and the stand may be formed of the above-described reflective material. In this case, the inclined surface of the stand corresponds to the reflective surface 32.

### Frame Body 40

The frame body 40 is located around the upper surface 12 of the substrate 10 as illustrated in FIG. 1B, and supports the cover 50 as illustrated in FIG. 1A. As illustrated in FIG. 1B, the frame body 40 surrounds the plurality of laser light sources 20 and the plurality of mirror members 30 in a top view. As illustrated in FIG. 1E, the frame body 40 has a first protruding portion 43a and a second protruding portion 43b which protrude inward from the inner surface to face each other.

As illustrated in FIG. 1E, the frame body 40 has a first upper surface 42a, the second upper surface 42b, and the third upper surface 42c. The second upper surface 42b is an upper surface of the first protruding portion 43a, and the third upper surface 42c is an upper surface of the second protruding portion 43b. The second upper surface 42b and the third upper surface 42c are located below the first upper surface 42a, and are surrounded by the first upper surface 42a in a top view.

A first bonding region 46a is provided on the first upper surface 42a. The first bonding region 46a has a substantially rectangular annular shape. The first bonding region 46a improves the bonding strength when the cover 50 is bonded to the frame body 40 via a bonding member such as a solder material. As illustrated in FIG. 1E, the first upper surface 42a and the first bonding region 46a surround the plurality of laser light sources 20 and the plurality of mirror members 30 in a top view.

In the example illustrated in FIG. 1E, the first bonding region 46a is provided in the entire first upper surface 42a, but the present invention is not limited to this example. The first bonding region 46a may be partially provided on the first upper surface 42a.

The first conductive region 48a is provided on the second upper surface 42b, and the second conductive region 48b is provided on the third upper surface 42c. As illustrated in FIG. 1E, the plurality of laser light sources 20 and the plurality of mirror members 30 are located between the second upper surface 42b and the third upper surface 42c and between the first conductive region 48a and the second conductive region 48b in a top view.

The electrical connection relationship among the first conductive region 48a, the second conductive region 48b, the upper surface of the submount 21, the semiconductor laser element 22, the protecting element 23, and the wire 41 is as follows. The first conductive region 48a is electrically connected to the semiconductor laser element 22 located at one end via some of the wires 41 and the upper surface of the submount 21. The second conductive region 48b is electrically connected to the semiconductor laser element 22 located at the other end via another part of the wires 41. Each semiconductor laser element 22 is electrically connected to the corresponding protecting element 23 via corresponding wire 41. The plurality of semiconductor laser elements 22 are electrically connected in series via the remaining wires 41 and the upper surfaces of the plurality of submounts 21.

The frame body 40 further has a first lower surface 44a and a second lower surface 44b, as illustrated in FIG. 1D. The second lower surface 44b partially has the lower surfaces of the first protruding portion 431 and the second protruding portion 43b illustrated in FIG. 1E, is located above the first lower surface 44a, and is surrounded by the first lower surface 44a in a bottom view as seen along the −Y direction. The second lower surface 44b has a substantially rectangular annular shape. Part or all of the substrate 10 illustrated in FIG. 1C is accommodated in a space surrounded by the step between the first lower surface 44a and the second lower surface 44b. If viewed through the frame body 40, the outer periphery of the second lower surface 44b surrounds the outer periphery of the upper surface 12 of the substrate 10 in a top view, and the inner periphery of the second lower surface 44b is surrounded by the outer periphery of the upper surface 12 of the substrate 10 in a top view.

A third conductive region 48c and a fourth conductive region 48d are provided in the first lower surface 44a. The third conductive region 48c is electrically connected to the first conductive region 48a via internal writing. The fourth conductive region 48d is electrically connected to the second conductive region 48b via the internal writing. Applying a voltage between the third conductive region 48c and the fourth conductive region 48d can supply power to the plurality of laser light sources 20 electrically connected in series as described above.

As illustrated in FIG. 1D, the frame body 40 has an opening portion 45 extending from the first upper surface 42a to the first lower surface 44a. The second lower surface 44b corresponding to a step is provided on the lower surface side of the inner surface in the opening portion 45. The second bonding region 46b is provided in the entire second lower surface 44b. The peripheral region of the upper surface 12 of the substrate 10 is bonded to the second bonding region 46b provided on the step via an inorganic bonding member such as a brazing material. The second bonding region 46b improves a bonding strength when the substrate 10 is bonded to the frame body 40 via the inorganic bonding member. The melting point of the brazing material is higher than the melting point of the solder material. Therefore, when the brazing material is heated to bond the substrate 10 and the frame body 40, and subsequently the solder material is heated to bond the substrate 10 and the laser light source 20, the possibility that the bonding of the substrate 10 and the frame body 40 may be disjointed due to the heat applied to the solder material can be reduced.

In the example illustrated in FIG. 1D, the second bonding region 46b is provided on the entire second lower surface 44b, but the present invention is not limited to this example. The second bonding region 46b may be provided in part of the second lower surface 44b.

The first lower surface 44a of the frame body 40 is positioned higher than the lower surface 14 of the substrate 10 as illustrated in FIG. 1F. In other words, a distance from the upper surface 12 of the substrate 10 to the lower surface 14 of the substrate 10 in the Y direction is longer than a distance from the upper surface 12 of the substrate 10 to the first lower surface 44a of the frame body 40 in the Y direction. Here, the distance in the Y direction from the upper surface 12 of the substrate 10 to the lower surface 14 of the substrate 10 means a distance in the Y direction from an uppermost portion of the upper surface 12 of the substrate 10 to the lower surface 14 of the substrate 10. The distance in the Y direction from the upper surface 12 of the substrate 10 to the first lower surface 44a of the frame body 40 means a distance in the Y direction from an uppermost portion of the upper surface 12 of the substrate 10 to the first lower surface 44a of the frame body 40.

When the light-emitting device 100 is disposed on a planar support surface, the lower surface 14 of the substrate 10 is supported by the support surface. The lower surface 14 of the substrate 10 is bonded to the support surface via a bonding member such as a solder material. When the lower surface 14 of the substrate 10 has a planar shape, the entire lower surface 14 is uniformly in contact with the support surface via the bonding member, and thus the light-emitting device 100 can be stably disposed. Furthermore, because the entire planar lower surface 14 of the substrate 10 is uniformly in contact with the support surface via the bonding member, heat generated from the laser light source 20 during driving can be effectively transferred to the support surface via the substrate 10. Further, when the light-emitting device 100 is disposed on a planar support surface, the bottom surface 15 of the recessed portion 13 is parallel to the lower surface 14 of the substrate 10, allowing for a more effective reduction of the deviation between the traveling direction of the laser beam L emitted to the outside of the light-emitting device 100 and the +Y direction which is the designed traveling direction.

The first lower surface 44a of the frame body 40 may be located on the same plane as the lower surface 14 of the substrate 10. In other words, the distance from the upper surface 12 of the substrate 10 to the lower surface 14 of the substrate 10 in the Y direction may be the same as the distance from the upper surface 12 of the substrate 10 to the first lower surface 44a of the frame body 40 in the Y direction. Alternatively, the first lower surface 44a of the frame body 40 may be positioned lower than the lower surface 14 of the substrate 10 as long as the first lower surface 44a does not interfere with the bonding of the substrate 10 to the support surface via the inorganic bonding member. In other words, a distance length from the upper surface 12 of the substrate 10 to the lower surface 14 of the substrate 10 in the Y direction may be shorter than a distance from the upper surface 12 of the substrate 10 to the first lower surface 44a of the frame body 40 in the Y direction.

The frame body 40 may be formed of ceramics selected from the group consisting of AlN, SiN, SiC, and alumina, for example. The thermal expansion coefficient of the frame body 40 can be, for example, 2×10⁻⁶ [1/K] or more to 15×10⁻⁶ [1/K] or less. The size of the frame body 40 in the X direction may be, for example, 3 mm or more and 30 mm or less, the maximum size thereof in the Y direction may be, for example, 1 mm or more and 5 mm or less, and the size thereof in the Z direction may be, for example, 3 mm or more and 30 mm or less.

The bonding regions 46a and 46b and the conductive regions 48a to 48d may be formed of, for example, at least one metal material selected from the group consisting of Ag, Cu, W, Au, Ni, Pt, and Pd. The conductive regions 48c and 48d can be formed by, for example, providing a metal film on the entire first lower surface 44a and patterning the metal film by etching.

### Cover 50

The cover 50 is supported by the first upper surface 42a of the frame body 40 illustrated in FIG. 1B. The cover 50 has an upper surface 52 and a lower surface 54 as illustrated in FIG. 1B, and supports the optical members 60 as illustrated in FIG. 1A. The lower surface 54 of the cover 50 faces the upper surface 12 of the substrate 10, and the upper surface 52 of the cover 50 is located opposite to the lower surface 54 of the cover 50. Because the lower surface 54 of the cover 50 faces the upper surface 12 of the substrate 10, it may be referred to as an “facing surface”. The cover 50 is located above the plurality of laser light sources 20. The cover 50 is also located above the plurality of mirror members 30.

The cover 50 transmits a plurality of the laser beams L emitted from the plurality of laser light sources 20 and reflected by the reflective surfaces 32 of the mirror members 30. The part of the cover 50 that transmits the laser beam L may have a transmittance of the laser beam L equal to or greater than 60%, for example, and preferably has a transmittance of the laser beam L equal to or greater than 80%. The remaining part of the cover 50 may have such light-transmissive properties or does not need to have such light-transmissive properties.

A bonding region 56 is provided on the periphery of the lower surface 54 of the cover 50. The bonding region 56 is bonded to the first bonding region 46a provided on the first upper surface 42a of the frame body 40 via a bonding member such as a solder material. The bonding region 56 improves the bonding strength when the cover 50 is bonded to the frame body 40 via the bonding member.

The cover 50 may be formed of, for example, at least one light-transmissive material selected from the group consisting of glass, silicon, quartz, synthetic quartz, sapphire, and transparent ceramics. The size of the cover 50 in the X direction may be, for example, 3 mm or more and 30 mm or less, for example, the size thereof in the Y direction may be, for example, 0.1 mm or more and 1.5 mm or less, for example, and the size thereof in the Z direction may be, for example, 1 mm or more and 30 mm or less, for example.

The bonding region 56 may be formed of, for example, the above-described metal material, similar to the bonding regions 46a and 46b and the conductive regions 48a to 48d. Similar to the conductive regions 48c and 48d, for example, the bonding region 56 can be formed by providing a metal film on the entire lower surface 54 of the cover 50 and patterning the metal film by etching.

In the example illustrated in FIGS. 1A and 1B, the cover 50 has a flat-plate shape, but the shape is not limited to this shape. In the light-emitting device 100, the cover 50 may have a box shape with an open lower portion. In the case of such a shape, the frame body 40 is bonded to the cover 50 so that the lower surface of the cover 50 is supported by the first upper surface 42a of the frame body 40.

### Optical Member 60

The optical member 60 is supported by the upper surface 52 of the cover 50 illustrated in FIG. 1B. As illustrated in FIG. 1B, the optical member 60 includes a flat-plate portion 60a having an upper surface 62 and a lower surface 64, and a plurality of lens portions 60b provided on the upper surface 62 of the flat-plate portion 60a. The flat-plate portion 60a and the plurality of lens portions 60b may be formed integrally, or may be formed separately and then bonded together. In the example illustrated in FIG. 1B, the plurality of lens portions 60b is connected, but the present invention is not limited to this example. The plurality of lens portions 60b may be separated. The number of lens portions 60b may be one or more. That is, the number of lens portions 60b is at least one. The number of lens portions 60b is preferably the same as the number of laser light sources 20.

Each lens portion 60b receives the laser beam L emitted from the corresponding laser light source 20, reflected by the reflective surface 32 of the corresponding mirror member 30, and transmitted through the cover 50. The laser beam L transmitted through the cover 50 spreads relatively fast in the YZ plane and spreads relatively slowly in the XY plane while traveling in the +Y direction parallel to the optical axis of each lens portion 60b. The fast axis direction of the laser beam L transmitted through the cover 50 is the Z direction, and the slow axis direction is the X direction. As illustrated in FIG. 1B, when the size of each lens portion 60b in the Z direction is larger than the size of each lens portion 60b in the X direction, the laser beam L that spreads while traveling in this manner can all be made incident on each lens portion 60b.

Each lens portion 60b collimates the laser beam L that spreads while traveling in the XY plane and the YZ plane. Alternatively, each lens portion 60b may diffuse or focus the laser beam L. In the present description, “collimate” means not only to make the laser beam L completely parallel light, but also to reduce the spread angle of the laser beam L.

The optical member 60 further includes a plurality of adjustment members 60c provided on the lower surface 64 of the flat-plate portion 60a. In the example illustrated in FIG. 1B, the number of adjustment members 60c is four, and the four adjustment members 60c are provided at the four corners of the lower surface 64 of the flat-plate portion 60a, but the present invention is not limited to this example. The number of the adjustment members 60c may be one or more. That is, the number of the adjustment members 60c is at least one. When the number of adjustment members 60c is one, the adjustment member 60c may have, for example, a U-shape or an annular shape in a bottom view. The adjustment member 60c having such a shape may be provided, for example, in part or all of the peripheral region of the lower surface 64 of the flat-plate portion 60a. At least one adjustment member 60c may be provided at any position in the lower surface 64 of the flat-plate portion 60a as long as the adjustment member 60c does not interfere with the travel of the laser beam L.

The adjustment member 60c is formed of, for example, an adhesive, and can be used to bond the optical member 60 and the cover 50 and to adjust the position of the optical member 60. To be more specific, the position of the focal point of each lens portion 60b can be adjusted by the adjustment member 60c to substantially coincide with part of the emission surface 22e of the corresponding semiconductor laser element 22 where the intensity of the laser beam L is highest. As a result, the laser beam L can be effectively collimated, diffused, or focused. Such adjustment of the focal position is performed in consideration of the fact that the optical path of the laser beam L is not a straight line but a polygonal line.

A portion of the optical member 60 that transmits the laser beam L may have the transmittance described above, similar to the cover 50. The remaining portion of the optical member 60 may or may not have such light-transmissive properties.

Similar to the cover 50, the optical member 60 may be formed of the above-described light-transmissive material. The material of the optical member 60 may be the same as or different from the material of the cover 50. The maximum size of the optical member 60 in the X direction may, for example, 3 mm or more and 30 mm or less, the maximum size thereof in the Y direction may be, for example, 0.1 mm or more and 1.5 mm or less, and the maximum size thereof in the Z direction may be, for example, 1 mm or more and 30 mm or less.

The optical member 60 may be a reflective member that reflects the laser beam L at a predetermined angle, instead of a lens that collimates, diffuses, or condenses the laser beam L.

As described above, in the light-emitting device 100 according to the present embodiment, the plurality of laser light sources 20 and the plurality of mirror members 30 are disposed on the bottom surface 15 having a planar shape of the recessed portion 13, thereby reducing the deviation between the traveling direction of the laser beam L emitted from each laser light source 20 and the +Z direction and reducing the deviation between the traveling direction of the laser beam L emitted from each laser light source 20 and reflected by the reflective surface 32 of the corresponding mirror member 30 and the +Y direction. As a result, the deviation between the traveling direction of the laser beam L emitted to the outside of the light-emitting device 100 and the +Y direction which is the designed traveling direction can be reduced.

Furthermore, in the light-emitting device 100 according to the present embodiment, when the light-emitting device 100 is disposed on a planar support surface, the entire planar lower surface 14 of the substrate 10 is uniformly in contact with the support surface via the bonding member, and thus the light-emitting device 100 can be stably disposed. Furthermore, because the entire planar lower surface 14 of the substrate 10 is uniformly in contact with the support surface via the bonding member, heat generated from the laser light source 20 during driving can be effectively transferred to the support surface via the substrate 10.

Furthermore, in the light-emitting device 100 according to the present embodiment, the bottom surface 15 of the recessed portion 13 and the lower surface 14 of the substrate 10 are parallel to each other and the light-emitting device 100 is disposed on a planar support surface, thereby more effectively reducing the deviation between the traveling direction of the laser beam L emitted to the outside of the light-emitting device 100 and the +Y direction which is the designed traveling direction.

### Modified Example of Light-Emitting Device 100

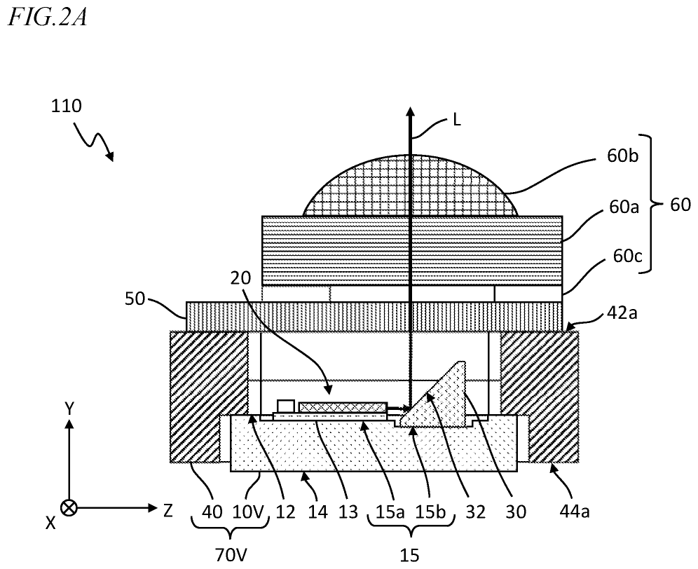

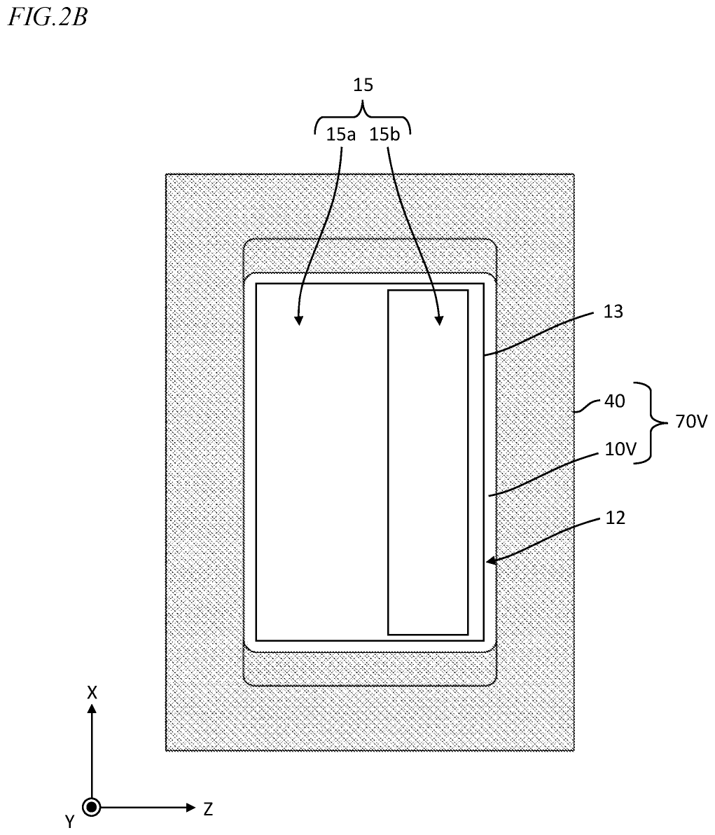

Next, a modified example of the light-emitting device 100 according to the present embodiment will be described with reference to FIGS. 2A and 2B. FIG. 2A is a cross-sectional view parallel to the YZ plane, schematically illustrating a configuration of a modified example of the light-emitting device 100 according to the present embodiment. A light-emitting device 110 illustrated in FIG. 2A is different from the light-emitting device 100 according to the present embodiment in that the light-emitting device 110 includes a substrate 10V instead of the substrate 10. In the present description, a configuration in which the substrate 10V is bonded to the frame body 40 are bonded to each other is also referred to as a “base portion 70V”. FIG. 2B is a top view of the configuration of the base portion 70V to be used for the light-emitting device 110 illustrated in FIG. 2A.

The substrate 10V has the upper surface 12 and the lower surface 14, as illustrated in FIG. 2A. The recessed portion 13 having the bottom surface 15 is provided on the upper surface 12. The bottom surface 15 of the recessed portion 13 has a first bottom surface 15a and a second bottom surface 15b. The first bottom surface 15a is a surface on which the plurality of laser light sources 20 are disposed. The second bottom surface 15b is a surface on which the plurality of mirror members 30 are disposed. The second bottom surface 15b is positioned lower than the first bottom surface 15a with the lower surface 14 of the substrate 10 as a height reference. Therefore, the bottom surface 15 has a step formed between the first bottom surface 15a and the second bottom surface 15b. The lower surface 14 of the substrate 10V is the same as the lower surface 14 of the substrate 10 illustrated in FIG. 1F.

When the distance in the Y direction from the highest point in the upper surface 12 to the first bottom surface 15a is a first depth of the recessed portion 13 by using the lower surface 14 of the substrate 10V as a height reference, the first depth of the recessed portion 13 can be, for example, 5 μm or more and 30 μm or less. When the distance in the Y direction from the highest point in the upper surface 12 to the second bottom surface 15b is a second depth of the recessed portion 13 by using the lower surface 14 of the substrate 10V as a height reference, the second depth of the recessed portion 13 can be, for example, 10 μm or more and 50 μm or less. The first bottom surface 15a and the second bottom surface 15b have a planar shape and are parallel to each other. Similar to the first bottom surface 15a and the second bottom surface 15b, the lower surface 14 has a planar shape. The first bottom surface 15a and the second bottom surface 15b are parallel to the lower surface 14. In this manner, the bottom surface 15 has a planar region. The same applies to the lower surface 14. The bottom surface 15 has a step between the first bottom surface 15a and the second bottom surface 15b, but has a planar region in the first bottom surface 15a and the second bottom surface 15b. The flatness of the first bottom surface 15a and the second bottom surface 15b is, for example, 10 μm or less, and the flatness of the lower surface 14 is, for example, 50 μm or less.

As illustrated in FIG. 2B, the second bottom surface 15b is surrounded by the first bottom surface 15a in a top view. In this case, where the second bottom surface 15b is located is easily confirmed, so that the plurality of mirror members 30 can easily be disposed on the second bottom surface 15b. In the example illustrated in FIG. 2B, the size of the second bottom surface 15b in the X direction is smaller than the size of the first bottom surface 15a in the X direction, but the size relationship between the two surfaces is not limited to this example. The size of the second bottom surface 15b in the X direction may be the same as the size of the first bottom surface 15a in the X direction. That is, in a top view, the second bottom surface 15b may be interposed between part of the first bottom surface 15a located in the +Z direction from the second bottom surface 15b and the remaining part of the first bottom surface 15a located in the −Z direction from the second bottom surface 15b. Even in this case, where the second bottom surface 15b is located is easily confirmed, so that the plurality of mirror members 30 can easily be disposed on the second bottom surface 15b. Part of the first bottom surface 15a located in the +Z direction with respect to the second bottom surface 15b does not have to be provided.

In the light-emitting device 110, making the second bottom surface 15b lower than the first bottom surface 15a allows the mirror member 30 to be disposed at a lower position compared to the light-emitting device 100 in which the second bottom surface 15b is not provided. As a result, even if the thickness of the submount 21 included in the laser light source 20 is further reduced, the laser beam L emitted from the semiconductor laser element 22 can be made incident on the reflective surface 32. Because the submount 21 can be made thinner, heat generated from the semiconductor laser element 22 during driving can be more effectively transferred from the submount 21 to the substrate 10V. As a result, heat generated from the laser light source 20 during driving can be more effectively transmitted to the support surface via the substrate 10V.

Further, in the light-emitting device 110, of the first bottom surface 15a and the second bottom surface 15b which have a planar shape and are parallel to each other, the plurality of laser light sources 20 are disposed on the first bottom surface 15a, and the plurality of mirror members 30 are disposed on the second bottom surface 15b. Each mirror member 30 is disposed to be located in front of the corresponding laser light source 20. Therefore, the deviation between the traveling direction of the laser beam L emitted from each laser light source 20 and the +Z direction can be reduced, and the deviation between the traveling direction of the laser beam L emitted from each laser light source 20 and reflected by the reflective surface 32 of the corresponding mirror member 30 and the +Y direction can be reduced. As a result, the deviation between the laser beam L emitted to the outside of the light-emitting device 110 and the +Y direction which is the designed traveling direction can be reduced. When the first bottom surface 15a, the second bottom surface 15b, and the lower surface 14 have a planar shape and are parallel to one another, the deviation between the laser beam L emitted to the outside of the light-emitting device 110 and the +Y direction which is the designed traveling direction can be more effectively reduced. The effect obtained by the lower surface 14 of the substrate 10V having a planar shape in the light-emitting device 110 is the same as the effect obtained by the lower surface 14 of the substrate 10 having a planar shape in the light-emitting device 100.

### Method for Manufacturing Light-Emitting Device

Hereinafter, a method for manufacturing the base portion 70 to be used for the light-emitting device 100 according to the present embodiment will be described with reference to FIGS. 3A to 3C. FIGS. 3A to 3C are cross-sectional views parallel to the YZ plane for illustrating an example of the process of the method for manufacturing the base portion 70 to be used for the light-emitting device 100 according to the present embodiment.

In the first step, as illustrated in FIG. 3A, a base body 71 in which a substrate 11 is bonded to the frame body 40 is provided. The substrate 11 has the upper surface 12 and the lower surface 14. The frame body 40 is located around the upper surface 12 of the substrate 11. The material of the substrate 11 is the same as the material of the substrate 10 illustrated in FIG. 1C. The material of the frame body 40 is as described above. As described above, in bonding the substrate 11 to the frame body 40 via an inorganic bonding member such as a brazing material, the thermal expansion coefficient of the substrate 11 higher than the thermal expansion coefficient of the frame body 40 may cause the substrate 11 to warp upward in a convex shape as illustrated in FIG. 3A due to heat applied to the inorganic bonding member.

In the subsequent step, the base body 71 is disposed in a press apparatus 80, as illustrated in FIG. 3B. The press apparatus 80 includes a stage 80a having an upper surface 82, a pressing portion 80b having a lower end 84, and a support member 80c that supports the pressing portion 80b and moves along the Y direction. The pressing portion 80b extends along the Y direction from the support member 80c. The upper surface 82 of the stage 80a and the lower end 84 of the pressing portion 80b have a planar shape parallel to the XZ plane and are parallel to each other. In the base body 71, at least part of the lower surface 14 of the substrate 11 is in contact with the upper surface 82 of the stage 80a. This is because the distance from the upper surface 12 of the substrate 11 to the lower surface 14 of the substrate 11 in the Y direction is longer than the distance from the upper surface 12 of the substrate 11 to the first lower surface 44a of the frame body 40 in the Y direction. Here, the distance in the Y direction from the upper surface 12 of the substrate 11 to the lower surface 14 of the substrate 11 means a distance in the Y direction from an uppermost portion of the upper surface 12 of the substrate 11 to a lowermost portion of the lower surface 14 of the substrate 11. The distance in the Y direction from the upper surface 12 of the substrate 11 to the first lower surface 44a of the frame body 40 means a distance in the Y direction from an uppermost portion of the upper surface 12 of the substrate 11 to the first lower surface 44a of the frame body 40.

In the subsequent step, the upper surface 12 of the substrate 11 is pressed by the lower end 84 of the pressing portion 80b, as illustrated in FIG. 3C. This pressing is performed so that, for example, by image recognition of the hole of the frame body 40 in a top view, the center of the lower end 84 of the pressing portion 80b in a bottom view coincides with the center of the hole. As a result, the recessed portion 13 having the bottom surface 15 is formed in the upper surface 12, and the substrate 10 is obtained. The substrate 11 illustrated in FIG. 3B is interposed between the stage 80a and the pressing portion 80b to become the substrate 10 illustrated in FIG. 3C. The shape of the recessed portion 13 is determined by the lower end 84 of the pressing portion 80b, and the shape of the lower surface 14 of the substrate 10 is determined by the upper surface 82 of the stage 80a. The pressing causes the bottom surface 15 of the recessed portion 13 and the lower surface 14 of the substrate 10 to have a planar shape parallel to the XZ plane and to be parallel to each other. The flatness of the bottom surface 15 of the recessed portion 13 depends on the flatness of the lower end 84 of the pressing portion 80b, and the flatness of the lower surface 14 of the substrate 10 depends on the flatness of the upper surface 82 of the stage 80a.

As illustrated in FIG. 1G, the pressing described above may press part of the upper surface 12 of the substrate 10 that is not in contact with the lower end 84 of the pressing portion 80b slightly upward to generate the raised portion 16. The raised portion 16 improves the visibility of the shape of the recessed portion 13, so that the plurality of laser light sources 20 and the plurality of mirror members 30 can easily be disposed on the bottom surface 15 of the recessed portion 13.

Through the above steps, the base portion 70 to be used for the light-emitting device 100 according to the present embodiment can be manufactured. As described above, the deviation between the traveling direction of the laser beam L emitted to the outside of the light-emitting device 100 and the designed traveling direction can be reduced by the simple process of providing the recessed portion 13 on the upper surface 12 of the substrate 10 by the press apparatus 80.

The method for manufacturing the light-emitting device 100 according to the present embodiment includes a step of disposing the plurality of laser light sources 20 on the bottom surface 15 of the recessed portion 13 in addition to the step of manufacturing the base portion 70 described above. The manufacturing method further includes a step of disposing the plurality of mirror members 30 on the bottom surface 15 of the recessed portion 13. When a plurality of surface-emitting semiconductor laser elements each of which emits the laser beam L in the +Y direction is disposed on the bottom surface 15 instead of the plurality of laser light sources 20, the step of disposing the plurality of mirror members 30 can be omitted.

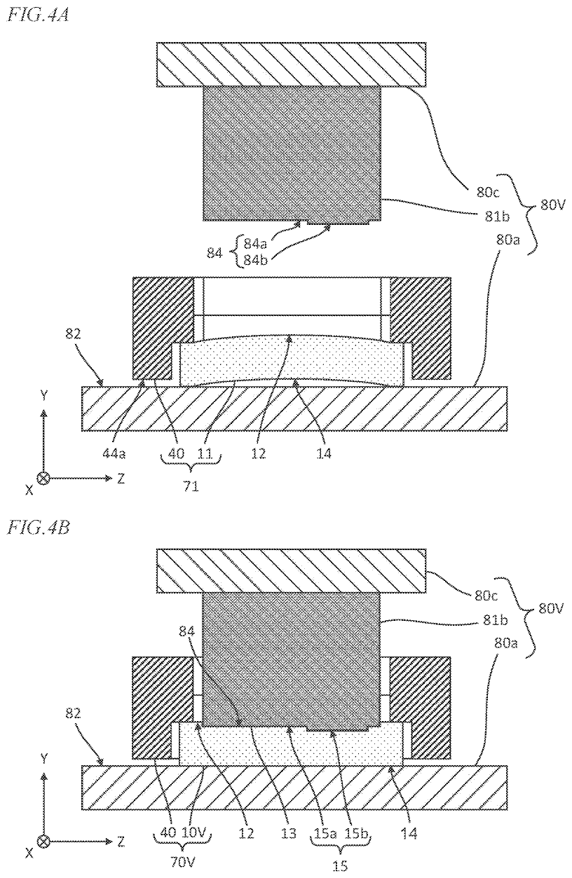

Next, with reference to FIGS. 4A and 4B, a method for manufacturing the base portion 70V to be used in the modified example of the light-emitting device 100 according to the present embodiment will be described. FIGS. 4A and 4B are cross-sectional views parallel to the YZ plane for illustrating an example of the process of the method for manufacturing the base portion 70V to be used in the modified example of the light-emitting device 100 according to the present embodiment.

In a step after the above-described base body 71 is provided, the base body 71 is disposed in a press apparatus 80V as illustrated in FIG. 4A. The press apparatus 80V includes a pressing portion 81b instead of the pressing portion 80b illustrated in FIG. 3B. The lower end 84 of the pressing portion 81b has a first lower end 84a and a second lower end 84b. The second lower end 84b is positioned lower than the first lower end 84a with the upper surface 82 of the stage 80a as a height reference. The upper surface 82 of the stage 80a and the first lower end 84a and the second lower end 84b of the pressing portion 81b have a planar shape parallel to the XZ plane and are parallel to each other. The size of the second lower end 84b in the X direction may be smaller than the size of the first lower end 84a in the X direction, and the second lower end 84b may be surrounded by the first lower end 84a in a bottom view. Alternatively, the size of the second lower end 84b in the X direction may be the same as the size of the first lower end 84a in the X direction, and the second lower end 84b may be interposed between part of the first lower end 84a located on the +Z direction side of the second lower end 84b and the remaining part of the first lower end 84a located on the −Z direction side of the second lower end 84b in a bottom view. In the subsequent step, as illustrated in FIG. 4B, the upper surface 12 of the substrate 11 is pressed by the lower end 84 of the pressing portion 81b by the press apparatus 80V. As a result, the recessed portion 13 is formed in the upper surface 12, and the substrate 10V is obtained. The shape of the recessed portion 13 is determined by the shape of the lower end 84 of the pressing portion 81b. The bottom surface 15 of the recessed portion 13 has the first bottom surface 15a and the second bottom surface 15b. The second bottom surface 15b is positioned lower than the first bottom surface 15a with the lower surface 14 of the substrate 10V as a height reference. The pressing the support member 80c causes the first bottom surface 15a and the second bottom surface 15b of the recessed portion 13 and the lower surface 14 of the substrate 10V to have a planar shape parallel to the XZ plane and to be parallel to one another. The flatness of the first bottom surface 15a of the recessed portion 13 depends on the flatness of the first lower end 84a of the pressing portion 81b, and the flatness of the second bottom surface 15b of the recessed portion 13 depends on the flatness of the second lower end 84b of the pressing portion 81b. The flatness of the lower surface 14 of the substrate 10V depends on the flatness of the upper surface 82 of the stage 80a, similar to the flatness of the lower surface 14 of the substrate 10 illustrated in FIG. 3B.

Through the above steps, the base portion 70V to be used in the modified example of the light-emitting device 100 according to the present embodiment can be manufactured. After the base portion 70 to be used for the light-emitting device 100 according to the present embodiment is manufactured, part of the bottom surface 15 of the recessed portion 13 may be pressed by another pressing portion. Because the bottom surface 15 has the first bottom surface 15a and the second bottom surface 15b by the pressing, the base portion 70V to be used in the modified example of the light-emitting device 100 according to the present embodiment is obtained.

The manufacturing method of the modified example of the light-emitting device 100 according to the present embodiment includes, in addition to the step of manufacturing the base portion 70V, a step of disposing the plurality of laser light sources 20 on the bottom surface 15 of the recessed portion 13 (more specifically, on the first bottom surface 15a), and a step of disposing the plurality of mirror members 30 on the bottom surface 15 of the recessed portion 13 (more specifically, on the second bottom surface 15b).

### Configuration of Laser Light Source 20

Hereinafter, each component of the laser light source 20 illustrated in FIG. 1C will be described. As illustrated in FIG. 1C, the submount 21 has an upper surface 21s1 and a lower surface 21s2 which are parallel to the XZ plane. A metal film is provided on each of the upper surface 21s1 and the lower surface 21s2. The metal film provided on the upper surface 21s1 can improve the bonding strength when the semiconductor laser element 22 is bonded to the submount 21 via a bonding member. The metal film provided on the upper surface 21s1 may further be used for supplying electric power to the semiconductor laser element 22. The metal film provided on the lower surface 21s2 can improve the bonding strength in bonding the substrate 10 and the laser light source 20 illustrated in FIG. 1C to each other via a bonding member. The metal film provided on each of the upper surface 21s1 and the lower surface 21s2 also serves to transfer heat generated in the semiconductor laser element 22 during driving to the substrate 10 via the submount 21. The submount 21 May be formed of, for example, the above-described ceramics, similar to the frame body 40 illustrated in FIG. 1C. The submount 21 may be formed of, for example, the above-described metal material, similar to the substrate 10 illustrated in FIG. 1C. Part or all of the submount 21 may be formed of, for example, at least one selected from the group consisting of AlN, SiC, alumina, CuW, Cu, a stacked structure of Cu/AlN/Cu, and a metal matrix compound (MMC). The MMC includes, for example, at least one selected from the group consisting of Cu, Ag, and Al and diamond. Alternatively, part or all of the submount 21 may be formed of another common material. The thermal expansion coefficient of the submount 21 can be, for example, 2×10⁻⁶ [1/K] or more and 20×10⁻⁶ [1/K] or less. Using the submount 21 having such a thermal expansion coefficient can reduce the possibility of its deformation due to heat applied to the bonding member in bonding the submount 21 to the semiconductor laser element 22 via a bonding member.

As illustrated in FIG. 1C, the semiconductor laser element 22 is supported by the upper surface 21s1 of the submount 21. The semiconductor laser element 22 has the emission surface 22e on one of two end surfaces intersecting the Z direction, and emits the laser beam from the emission surface 22e in the +Z direction. The laser beam spreads at different speeds in the YZ plane and the XZ plane as it travels in the +Z direction. The laser beam spreads relatively fast in the YZ plane and relatively slow in the XZ plane. When the laser beam is not collimated, the spot of the laser beam has an elliptical shape having a major axis in the Y direction and a minor axis in the X direction in the XY plane in the far field.

Part of the laser beam having an intensity of 1/e² or more of the peak intensity in any plane perpendicular to the traveling direction of the laser beam is defined as a main part. e is the base of a natural logarithm. In the present description, the spread of the laser beam means the spread of the main part of the laser beam.

The semiconductor laser element 22 can emit a violet, blue, green, or red laser beam in the visible region or an infrared or ultraviolet laser beam in the invisible region. The light emission peak wavelength of the violet light is preferably in a range of 400 nm or more and 420 nm or less and more preferably in a range of 400 nm or more and 415 nm or less. The light emission peak wavelength of the blue light is preferably in a range of 420 nm or more and 495 nm or less and more preferably in a range of 440 nm or more and 475 nm or less. The light emission peak wavelength of the green light is preferably in a range of 495 nm or more and 570 nm or less and more preferably in a range of 510 nm or more and 550 nm or less. The light emission peak wavelength of the red light is preferably in a range of 605 nm or more and 750 nm or less and more preferably in a range of 610 nm or more and 700 nm or less.

Examples of the semiconductor laser element 22 that emits a violet, blue, and green laser beam include laser diodes containing a nitride semiconductor material. For example, GaN, InGaN, and AlGaN can be used as the nitride semiconductor material. Examples of the semiconductor laser element 22 that emits a red laser beam include a laser diode including an InAlGaP-based, GaInP-based, GaAs-based, or AlGaAs-based semiconductor material.

As illustrated in FIG. 1C, the protecting element 23 is supported by the upper surface 21s1 of the submount 21. The protecting element 23 may be disposed, for example, obliquely rearward of the semiconductor laser element 22. In this case, the protecting element 23 does not prevent the laser beam L emitted from the semiconductor laser element 22 from traveling. Furthermore, the protecting elements 23 may be disposed so as not to overlap a virtual straight line that passes through the center of the emission surface 22e and extends in a direction perpendicular to the emission surface 22e in a top view. In this case, the protecting element 23 is less likely to be affected by light leaking from the rear surface of the semiconductor laser element 22 located on the opposite side of the emission surface 22e.

The protecting element 23 can be, for example, a Zener diode. The Zener diode may be formed of Si, for example.

The light-emitting device of the present disclosure can be used for devices such as a projector and light source for a lighting device.

What is claimed is:

1. A method for manufacturing a base portion for a light-emitting device, the method comprising:
providing a base body, the base body including
a substrate formed of a metal material, the substrate having an upper surface, and
a frame body formed of ceramics, the frame body being located around the upper surface of the substrate; and
forming a recessed portion in the upper surface of the substrate, the recessed portion having a bottom surface including a planar region.

2. The method for manufacturing a base portion according to claim 1, wherein
the bottom surface of the recessed portion and a lower surface of the substrate are parallel to each other.

3. The method for manufacturing a base portion according to claim 1, wherein
the bottom surface of the recessed portion has a first bottom surface and a second bottom surface,
a distance between the second bottom surface and a lower surface of the substrate is shorter than a distance between the first bottom surface and the lower surface of the substrate, and
the first bottom surface, the second bottom surface, and the lower surface of the substrate are parallel to one another.

4. The method for manufacturing a base portion according to claim 1, wherein
the providing of the base body includes bonding the substrate to the frame body via an inorganic bonding member.

5. A method for manufacturing a light-emitting device, the method comprising:
manufacturing a base portion by the method for manufacturing a base portion according to claim 1; and
disposing a semiconductor laser element on the bottom surface of the recessed portion.

6. The method for manufacturing a light-emitting device according to claim 5, further comprising
disposing a mirror member on the bottom surface of the recessed portion.

7. The method for manufacturing a light-emitting device according to claim 5, further comprising
disposing at least one additional semiconductor laser element on the bottom surface of the recessed portion.

8. A method for manufacturing a light-emitting device, the method comprising:
manufacturing a base portion by the method for manufacturing a base portion according to claim 3;
disposing a semiconductor laser element on the first bottom surface of the recessed portion; and
disposing a mirror member on the second bottom surface of the recessed portion.

9. The method for manufacturing a light-emitting device according to claim 8, further comprising
disposing at least one additional semiconductor laser element on the first bottom surface of the recessed portion, and
disposing at least one additional mirror member on the second bottom surface of the recessed portion.

10. The method for manufacturing a light-emitting device according to claim 5, wherein
the providing of the base body includes providing the substrate and the frame body such that a distance from the upper surface of the substrate to a lower surface of the substrate is longer than a distance from the upper surface of the substrate to a lower surface of the frame body.

11. A light-emitting device comprising:
a substrate formed of a metal material and having an upper surface, the upper surface defining a recessed portion having a bottom surface, the bottom surface including a planar region;
a semiconductor laser element disposed on the bottom surface of the recessed portion and configured to emit a laser beam;
a mirror member disposed on the bottom surface of the recessed portion and configured to reflect the laser beam to change a traveling direction of the laser beam in a direction away from the upper surface of the substrate; and
a frame body formed of ceramics and surrounding the semiconductor laser element and the mirror member.

12. The light-emitting device according to claim 11, wherein
the substrate has a planar lower surface located opposite to the upper surface.

13. The light-emitting device according to claim 11, further comprising
at least one additional semiconductor laser element disposed on the bottom surface of the recessed portion.

14. The light-emitting device according to claim 11, wherein
the bottom surface of the recessed portion and a lower surface of the substrate are parallel to each other.

15. The light-emitting device according to claim 14, wherein
flatness of the bottom surface of the recessed portion is 10 μm or less, and
flatness of the lower surface of the substrate is 50 μm or less.

16. The light-emitting device according to claim 11, wherein
the bottom surface of the recessed portion has a first bottom surface supporting the semiconductor laser element and a second bottom surface supporting the mirror member, and
a distance between the second bottom surface and a lower surface of the substrate is shorter than a distance between the first bottom surface and the lower surface of the substrate.

17. The light-emitting device according to claim 16, wherein
the first bottom surface and the second bottom surface have a planar shape and are parallel to each other.

18. The light-emitting device according to claim 11, wherein
a distance from the upper surface of the substrate to a lower surface of the substrate is longer than a distance from the upper surface of the substrate to a lower surface of the frame body.

19. The light-emitting device according to claim 11, wherein
the frame body defines an opening portion extending from an upper surface to a lower surface,
the frame body has a step provided on a lower surface side of an inner surface in the opening portion, and
a peripheral region of the upper surface of the substrate is bonded to the step of the frame body.

20. The light-emitting device according to claim 19, wherein
a distance from the upper surface to a lower surface of the substrate is longer than a distance from the upper surface of the substrate to a lower surface of the frame body.

21. The light-emitting device according to claim 19, wherein
the peripheral region of the upper surface of the substrate is bonded to the step of the frame body via an inorganic bonding member.
